(19) United States
(12) Patent Application Publication
(10) Pub. No.: US 2020/0403142 A1
(43) Pub. Date: Dec. 24, 2020

(54) PIEZOELECTRIC TRANSDUCER ARRAY FABRICATION

(71) Applicant: uBeam Inc., Marina Del Rey, CA (US)

(72) Inventors: Iman Shahosseini, Woodland Hills, CA (US); Trevor Niblock, Agoura, CA (US); Wade Smith, Santa Monica, CA (US); Henry Tri, Covina, CA (US); Richard Agbulos, Chatsworth, CA (US); Bo Pham, Woodland Hills, CA (US)

(21) Appl. No.: 16/446,424

(22) Filed: Jun. 19, 2019

(51) Int. Cl. H01L 41/311; H01L 41/338; H01L 41/313

(52) U.S. Cl. CPC H01L 41/311; H01L 41/313; H01L 41/338

(57) ABSTRACT

Systems and techniques are provided for piezoelectric transducer array fabrication. A sheet of piezoelectric material may be diced into pieces of piezoelectric material. A sheet of elastic layer material may be spin coated with adhesive. The pieces of piezoelectric material may be placed onto the sheet of elastic layer material. Pressure may be applied to the pieces of piezoelectric material and the sheet of elastic layer material. The adhesive may be cured. Transduction elements may be cut from the pieces of piezoelectric material and the sheet of elastic layer material. Electronics may be mounted on a PCB mounting board. Adhesive may be applied onto the PCB mounting board. The transduction elements may be mounted on the PCB mounting board. A spacer may be mounted on the PCB mounting board. Adhesive may be applied onto the spacer and the transduction elements. Diaphragms may be mounted on the spacer.

### BACKGROUND

Piezoelectric transducers may be used to generate soundwaves at various frequencies, including ultrasonic frequencies. A piezoelectric transducer array may include multiple piezoelectric transducers. Piezoelectric transducers may be manufactured in an array or by processing individual transducers in parallel and then arraying them together.

### BRIEF SUMMARY

According to an implementation of the disclosed subject matter, a sheet of piezoelectric material may be diced into pieces of piezoelectric material. A sheet of elastic layer material may be spin coated with adhesive. The pieces of piezoelectric material may be placed onto the sheet of elastic layer material. Pressure may be applied to the pieces of piezoelectric material and the sheet of elastic layer material. The adhesive may be cured. Transduction elements may be cut from the pieces of piezoelectric material and the sheet of elastic layer material. Electronics may be mounted on a PCB mounting board including traces and vias. Adhesive may be applied to the PCB mounting board by screen printing or film patterning. The transduction elements may be mounted on the PCB mounting board. A spacer may be mounted on the PCB mounting board. Adhesive may be applied to the spacer and the transduction elements by screen printing or film patterning. Diaphragms may be mounted on the spacer.

Additional features, advantages, and embodiments of the disclosed subject matter may be set forth or apparent from consideration of the following detailed description, drawings, and claims. Moreover, it is to be understood that both the foregoing summary and the following detailed description are examples and are intended to provide further explanation without limiting the scope of the claims.

### BRIEF DESCRIPTION OF THE DRAWINGS

The accompanying drawings, which are included to provide a further understanding of the disclosed subject matter, are incorporated in and constitute a part of this specification. The drawings also illustrate embodiments of the disclosed subject matter and together with the detailed description serve to explain the principles of embodiments of the disclosed subject matter. No attempt is made to show structural details in more detail than may be necessary for a fundamental understanding of the disclosed subject matter and various ways in which it may be practiced.

FIG. 1A shows an example sheet of piezoelectric material according to an implementation of the disclosed subject matter.

FIG. 1B shows an example sheet of piezoelectric material according to an implementation of the disclosed subject matter.

FIG. 1C shows an example cross-sectional view of a sheet of piezoelectric material according to an implementation of the disclosed subject matter.

FIG. 2A shows an example sheet of piezoelectric material according to an implementation of the disclosed subject matter.

FIG. 2B shows an example sheet of piezoelectric material according to an implementation of the disclosed subject matter.

FIG. 2C shows an example cross-sectional view of a sheet of piezoelectric material according to an implementation of the disclosed subject matter.

FIG. 3A, FIG. 3B, and FIG. 3C show example pieces of piezoelectric material according to an implementation of the disclosed subject matter.

FIG. 4A shows an example sheet of elastic layer material according to an implementation of the disclosed subject matter.

FIG. 4B shows an example sheet of elastic layer material according to an implementation of the disclosed subject matter.

FIG. 4C shows an example cross-sectional view of a sheet of elastic layer material according to an implementation of the disclosed subject matter.

FIG. 5A shows an example sheet of elastic layer material with pieces of piezoelectric material according to an implementation of the disclosed subject matter.

FIG. 5B shows an example sheet of elastic layer material with pieces of piezoelectric material according to an implementation of the disclosed subject matter.

FIG. 5C shows an example cross-sectional view of a sheet of elastic layer material with pieces of piezoelectric material according to an implementation of the disclosed subject matter.

FIG. 6A shows an example sheet of elastic layer material with pieces of piezoelectric material according to an implementation of the disclosed subject matter.

FIG. 6B shows an example sheet of elastic layer material with pieces of piezoelectric material according to an implementation of the disclosed subject matter.

FIG. 6C shows an example cross-sectional view of a sheet of elastic layer material with pieces of piezoelectric material according to an implementation of the disclosed subject matter.

FIG. 7A, FIG. 7B, and FIG. 7C shows example transduction elements according to an implementation of the disclosed subject matter.

FIG. 8A shows an example PCB mounting board according to an implementation of the disclosed subject matter.

FIG. 8B shows an example PCB mounting board according to an implementation of the disclosed subject matter.

FIG. 8C shows an example cross-sectional view of a PCB mounting board according to an implementation of the disclosed subject matter.

FIG. 9A shows an example PCB mounting board and electronics according to an implementation of the disclosed subject matter.

FIG. 9B shows an example PCB mounting board and electronics according to an implementation of the disclosed subject matter.

FIG. 10A shows an example PCB mounting board and electronics according to an implementation of the disclosed subject matter.

FIG. 10B shows an example PCB mounting board and electronics according to an implementation of the disclosed subject matter.

FIG. 10C shows an example cross-sectional view of a PCB mounting board and electronics according to an implementation of the disclosed subject matter.

FIG. 11A shows an example PCB mounting board, electronics, and transduction elements according to an implementation of the disclosed subject matter.

FIG. 11B shows an example PCB mounting board, electronics, and transduction elements according to an implementation of the disclosed subject matter.

FIG. 11C shows an example cross-sectional view of a PCB mounting board, electronics, and transduction elements.

FIG. 12A shows an example PCB mounting board, electronics, transduction elements, and spacer according to an implementation of the disclosed subject matter.

FIG. 12B shows an example PCB mounting board, electronics, transduction elements, and spacer according to an implementation of the disclosed subject matter.

FIG. 12C shows an example cross-sectional view of a PCB mounting board, electronics, transduction elements, and spacer.

FIG. 13A shows an example PCB mounting board, electronics, transduction elements, and spacer according to an implementation of the disclosed subject matter.

FIG. 13B shows an example PCB mounting board, electronics, transduction elements, and spacer according to an implementation of the disclosed subject matter.

FIG. 13C shows an example cross-sectional view of a PCB mounting board, electronics, transduction elements, and spacer.

FIG. 14A shows an example diaphragm according to an implementation of the disclosed subject matter.

FIG. 14B shows an example diaphragm according to an implementation of the disclosed subject matter.

FIG. 14C shows an example cross-sectional view of a diaphragm according to an implementation of the disclosed subject matter.

FIG. 15A shows an example piezoelectric transducer array according to an implementation of the disclosed subject matter.

FIG. 15B shows an example piezoelectric transducer array according to an implementation of the disclosed subject matter.

FIG. 15C shows an example cross-sectional view of a piezoelectric transducer array according to an implementation of the disclosed subject matter.

FIG. 16A shows an example piezoelectric transducer array according to an implementation of the disclosed subject matter.

FIG. 16B shows an example piezoelectric transducer array according to an implementation of the disclosed subject matter.

FIG. 16C shows an example cross-sectional view of a piezoelectric transducer array according to an implementation of the disclosed subject matter.

FIG. 17A shows an example piezoelectric transducer array according to an implementation of the disclosed subject matter.

FIG. 17B shows an example piezoelectric transducer array according to an implementation of the disclosed subject matter.

FIG. 17C shows an example cross-sectional view of a piezoelectric transducer array according to an implementation of the disclosed subject matter.

FIG. 18A shows an example single component spacer and diaphragm according to an implementation of the disclosed subject matter.

FIG. 18B shows an example single component spacer and diaphragm according to an implementation of the disclosed subject matter.

FIG. 18C shows an example cross-sectional view of a single component spacer and diaphragm according to an implementation of the disclosed subject matter.

FIG. 19A shows an example single component diaphragm and waveguide according to an implementation of the disclosed subject matter.

FIG. 19B shows an example piezoelectric transducer array according to an implementation of the disclosed subject matter.

FIG. 19C shows an example cross-sectional view of a piezoelectric transducer array according to an implementation of the disclosed subject matter.

FIG. 20 shows an example procedure suitable for piezoelectric transducer array fabrication according to an implementation of the disclosed subject matter.

FIG. 21 shows an example procedure suitable for piezoelectric transducer array fabrication according to an implementation of the disclosed subject matter.

FIG. 22 shows an example procedure suitable for piezoelectric transducer array fabrication according to an implementation of the disclosed subject matter.

FIG. 23 shows an example procedure suitable for piezoelectric transducer array fabrication according to an implementation of the disclosed subject matter.

FIG. 24 shows an example procedure suitable for piezoelectric transducer array fabrication according to an implementation of the disclosed subject matter.

FIG. 25 shows an example procedure suitable for piezoelectric transducer array fabrication according to an implementation of the disclosed subject matter.

### DETAILED DESCRIPTION

A piezoelectric transducer array may be fabricated using batch processing. A piezoelectric transducer array may be fabricated to serve as a tile in a device for sending and/or receiving waves, such as sound waves. Tiles may be fabricated in various sizes. A sheet of piezoelectric material may be diced. An elastic layer may be spin coated with adhesive. The diced pieces of the sheet of piezoelectric material may be placed on the elastic layer. The elastic layer may be laser-cut or chemically etched to create individual transduction elements. Electronics may be mounted on the back of a PCB mounting board that may be prepared with electrical vias and traces on its top and bottom sides. Conductive adhesive may be applied by screen printed or film patterning onto the top side of the PCB mounting board. The transduction elements may be mounted on the PCB mounting board. A spacer may be mounted on the PCB mounting board. Conductive adhesive may be applied by screen printing or film patterning on top of the spacer and at the centers of the tops of the transduction elements. Diaphragms may be mounted on to the spacer and the transduction elements. Adhesive may be applied by screen printing or film patterning on the top sides of the diaphragms. Waveguides and protection grids may be mounted on top of the diaphragms.

A sheet of piezoelectric material may be diced. The sheet of piezoelectric material may be any suitable piezoelectric material, such as any suitable piezoceramic. The dicing of the sheet of piezoelectric material may be performed in any suitable manner, using any suitable equipment or devices. The dicing of the sheet of piezoelectric material may produce multiple separate pieces of piezoelectric material. The pieces of piezoelectric material may have any suitable shape, such as, for example, rectangular, and any suitable dimensions, such as, for example, 5.8 mm long×5.8 mm wide×0.19 mm high. The sheet of piezoelectric material may be diced to produce pieces of piezoelectric material that are of the same size and shape.

A sheet of elastic layer material may be spin coated with adhesive. The sheet of elastic layer material may be made of any suitable elastic material, such as, for example, iron-nickel alloys such as invar, aluminum, silicon, titanium, nickel, brass, steel, magnesium, or copper. Spin coating, using any suitable equipment, may be used to coat the sheet of elastic layer material with any suitable adhesive, such as, for example, an electrically conductive adhesive. Adhesive may also be applied to the sheet of elastic layer material as adhesive drops dispensed onto the sheet of elastic layer material. Alternatively, adhesive films may be used by patterning and peeling off the excess sections.

The pieces of piezoelectric material may be placed onto the adhesive on the sheet of elastic layer material. The pieces of piezoelectric material may be arranged on the sheet of elastic layer material in any suitable pattern, and with any suitable spacing between the pieces of piezoelectric material. For example, the pieces of piezoelectric material may be arranged in a grid pattern on the sheet of elastic layer material. Any suitable equipment may be used to place the pieces of piezoelectric material. Pressure may be applied to the pieces of piezoelectric material and sheet of elastic layer material and the adhesive may be cured. Pressure may be applied in any suitable manner, using any suitable equipment. The adhesive may be cured in any suitable manner. The curing temperature may be kept well below the curie temperature of the piezoelectric material to prevent any material properties degradation. For example, the curing temperature may be kept below 110 degrees Celsius.

The sheet of elastic layer material may be laser-cut or chemically etched to create individual transduction elements. For example, laser-cutting or chemical etching may be used to cut the sheet of elastic layer material into shapes around each of the pieces of the piezoelectric material adhered to the sheet of elastic layer material. The shapes may be any suitable shape, such as, for example, rectangles, irregular hexagons, or irregular octagons. The laser-cutting or chemical etching of the sheet of elastic layer material may create individual transduction elements. A transduction element may be a bimorph structure that may include a single piece of piezoelectric material mounted on top of an elastic layer that is a piece of the sheet of elastic layer material.

Electronics may be mounted on the back of a PCB mounting board that may be prepared with electrical vias and traces on its top and bottom sides. For example, a PCB mounting board may be prepared with electrical vias and traces that may be able to provide electrical connections for multiple transduction elements. The PCB mounting board may have two vias for every transduction element that will be attached to the PCB mounting board. Electronics may be mounted on the back side of the PCB mounting board. The electronics may be, for example, drivers, rectifiers, voltage regulators, super-capacitors, or other electronic devices use to provide power to, receive power from, and control the transduction elements. The electronics may be mounted as discrete components or may be in the form of ASICs or other integrated circuits. The electronics may be mounted in any suitable manner, such as, for example, through soldering.

Conductive adhesive may be applied onto the top side of the PCB mounting board. Any suitable electrically conductive adhesive may be screen printed or film patterned onto the top side of the PCB mounting board using any suitable screen-printing or film transfer techniques and equipment. The adhesive may be screen printed or film patterned in any suitable pattern. For example, the adhesive may be screen printed or film patterned so that each of the vias of the PCB mounting board may be covered with adhesive while not creating an electrical connection between any two vias through the adhesive, which may short circuit transducers. The adhesive may also be screen printed or film patterned so that a transduction element may be placed with one end of the transduction element on adhesive covering a via and the other end of the transduction element on adhesive that is not covering a via. The adhesive may also be screen printed or film patterned to allow a spacer to be adhered to the PCB mounting board around the transduction elements.

The transduction elements may be mounted on the PCB mounting board. The transduction elements may be mounted on the PCB mounting board by placing the transduction elements directly onto the adhesive applied to the mounting board. The transduction elements may be mounted on the PCB mounting board in any suitable pattern. For example, the transduction elements may be mounted in a hexagonal tiling pattern. Each transduction element may be placed so that one end of the transduction element is placed on the adhesive covering a via on the PCB mounting board and the other end is placed on adhesive that does not cover a via. In some implementations, standoffs may be mounted between transduction elements and the PCB mounting board. A standoff, which may be made of any suitable electrically conductive material, may be placed on adhesive on the PCB mounting board, and may have adhesive applied to the top side of the standoff. A transduction element may be placed on the adhesive on the top side of the standoff. Standoffs may be used to adjust the height of the transduction elements relative to the PCB mounting board.

A spacer may be mounted on the PCB mounting board. The spacer may be made of an electrically conductive material or may be made of a non-electrically conductive material and have vias. The spacer may have any suitable shape and pattern. For example, the spacer may be walls around empty cells in a hexagonal tiling pattern. Each empty cell of the spacer may be of a suitable size to fit around a transduction element. The spacer may be placed on the PCB mounting board so that all, or portions, of the bottom of the walls of the spacer are on the adhesive on the PCB mounting board, including adhesive that covers the vias that are not covered by the transduction elements. If the spacer is made of a non-electrically conductive material, vias in the spacer may be aligned with the vias that are not covered by the transduction elements. The walls of the spacer may be of any suitable height, and may, for example, be taller than transduction elements. Depending on the configuration of the electronics used to drive the piezoelectric transducers, a spacer that includes vias and is made of a non-electrically conductive material may be used so that there is no common node between the piezoelectric transducers in an array.

Conductive adhesive may be applied on top of the spacer and at the centers of the tops of the transduction elements. Any suitable electrically conductive adhesive may be screen printed or film patterned onto the top of the walls of the spacer and at the centers of the tops of the transduction elements using any suitable screen-printing or film transfer techniques and equipment. The adhesive may be screen printed or film patterned to cover the entirety of the top of the walls of the spacer or may be printed in any other suitable pattern onto the top of the walls of the spacer.

Diaphragms may be mounted on to the spacer and the transduction elements. Diaphragms made of an electrically conductive material may be mounted on to the adhesive on the top of the walls of the spacer, with the center of each diaphragm being mounted on the adhesive on the center at the top of one of the transduction elements. A diaphragm may be made of any suitable electrically conductive material, such as, for example, aluminum. A diaphragm may be in any suitable shape, such as, for example, a cup or bowl. A diaphragm may include a perimeter around the cup or bowl. The perimeter of a diaphragm may be mounted on the adhesive on the top of the walls of the spacer while the center of the cup of the diaphragm may be mounted on the adhesive on the center at the top of one of the transduction elements.

Adhesive may be applied on the top sides of the diaphragms. Any suitable electrically conductive adhesive may be screen printed or film patterned onto the perimeters of the diaphragms using any suitable screen-printing or film transfer techniques and equipment. The adhesive may be screen printed or film patterned to cover the entirety of the perimeters of the diaphragms or may be printed in any other suitable pattern onto the perimeters of the diaphragm.

Waveguides and protection grids may be mounted on top of the diaphragm. The waveguides may, for example, be attached to the diaphragms on adhesive screen printed or adhesive film applied on the perimeters of the diaphragms. The protection grids may be attached to the top of the waveguides. The waveguides and protection grids may be made from any suitable materials, such as, for example, plastics, silicones, papers, cloths, fiberglass, carbon fiber, or polymers generally. The waveguides may have any suitable shape. For example, the waveguides may be rings with walls of a tapered thickness that may be thicker at the base of the waveguide and thinner at the top of the waveguide, or be in hexagonal shape, for example, similar to a honeycomb structure. The waveguides may be separate components or may be joined as a single component with a pattern that may align with the perimeters of the diaphragms. The protection grids may be a grid of any suitable type and grid pattern, with any suitable grid density.

In some implementations, the diaphragms and spacer may be a single integral piece. A single piece spacer/diaphragm may be mounted on the adhesive on the PCB mounting board. No application of adhesive onto the spacer may be needed.

In some implementations, the diaphragms and waveguide may be a single integral piece. A single piece diaphragm/waveguide may be mounted on the adhesive on the top of the walls of the spacer. No application of adhesive onto the perimeter of the diaphragms may be needed.

In some implementations, adhesive may be screen printed or film patterned onto the top of the walls of the spacer before the spacer is mounted on the PCB mounting board. The diaphragms may be mounted on the spacer, and the waveguide may optionally be mounted on the diaphragms. Adhesive may then be applied to the centers of the bottom sides of the cups of the diaphragms and/or at the centers of the tops of the transduction elements, for example, through screen printing, adhesive film transfer, or any other suitable adhesive application process. The spacer, with attached diaphragms, may then be mounted on the PCB mounting board, with the centers of the bottom sides of the cups of the diaphragms being mounted on the centers of the tops of the transduction elements.

The piezoelectric transducer array may include circuits that may allow electrical signals to be applied to the transduction elements without wire or wire-bond. The PCB mounting board may connect the transduction elements of the piezoelectric transducer array to a power source, power storage, and/or electrical load. For example, the transduction elements may be connected to a battery. The battery may be able to supply electrical voltage to cause the pieces of piezoelectric material in the transduction elements to flex, in turn flexing the diaphragms and producing sound waves. The battery may also be able to store electrical energy based on voltage generated by flexing of the piezoelectric material caused by sound waves that cause the diaphragms to flex. The battery may serve as a power source and power storage. The power source and power storage may also be, for example, capacitor, super-capacitor, or a circuit connected to an outside power source, such as a wall outlet. An electrical load may be, for example, any suitable electronic or electric devices or components, such as, for example, the components of a computing device such as a smartwatch, smartphone, tablet, or laptop, or smart television, an amplifier or powered speaker system, any IOT device such as sensor tags or GPS trackers, RFID sensors, security cameras, or wireless keyboards and mice, or an appliance of any suitable type.

A piezoelectric transducer array may be fabricated to include any number of piezoelectric transducers. Piezoelectric transducers in the same piezoelectric transducer array may share electrical and electronic components, including components and circuits for controlling, providing power to, and receiving power from transduction elements of the piezoelectric transducers.

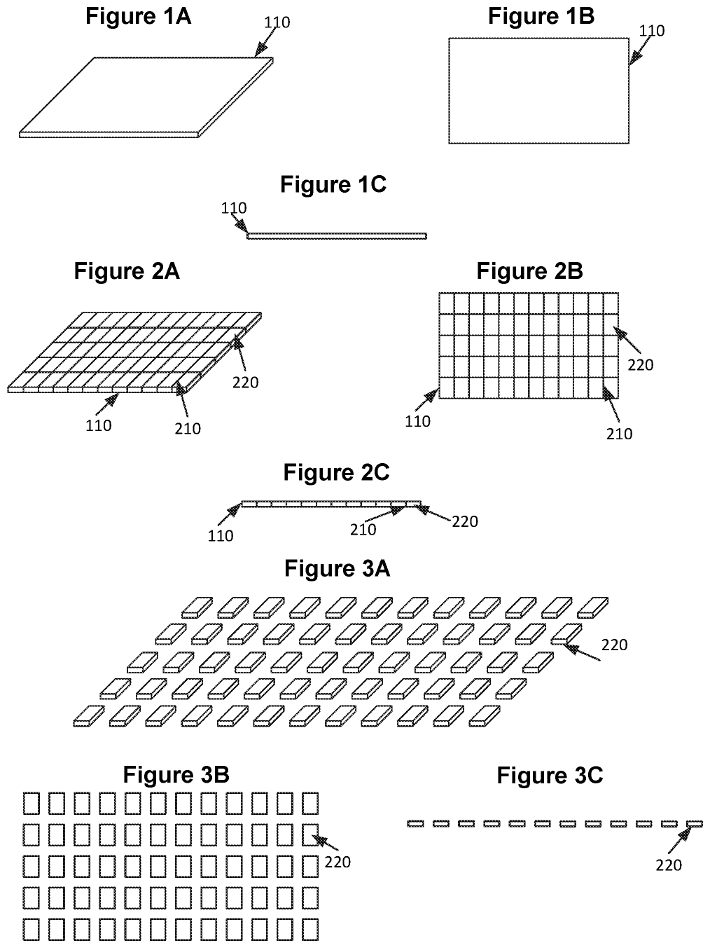

FIG. 1A shows an example sheet of piezoelectric material according to an implementation of the disclosed subject matter. A sheet of piezoelectric material 110 may be any suitable piezoelectric material, such as any suitable piezoceramic.

FIG. 1B shows an example sheet of piezoelectric material according to an implementation of the disclosed subject matter. The sheet of piezoelectric material 110 may have any suitable dimensions, including any suitable length and width.

FIG. 1C shows an example cross-sectional view of a sheet of piezoelectric material according to an implementation of the disclosed subject matter. The sheet of piezoelectric material 110 may have any suitable dimensions, including any suitable thickness. The thickness of the sheet of piezoelectric material 110 may be the thickness desired for pieces of piezoelectric material that may be used in transduction elements of a piezoelectric transducer.

FIG. 2A shows an example sheet of piezoelectric material according to an implementation of the disclosed subject matter. The sheet of piezoelectric material 110 may be diced or laser cut. The dicing of the sheet of piezoelectric material 110 may be performed in any suitable manner, using any suitable equipment or devices. The sheet of piezoelectric material 110 may be diced along lines 210, resulting in pieces of piezoelectric material 220.

FIG. 2B shows an example sheet of piezoelectric material according to an implementation of the disclosed subject matter. The sheet of piezoelectric material 110 may be diced or laser cut to produce pieces of piezoelectric material 220 of any suitable shapes and dimensions. For example, the pieces of piezoelectric material 220 may be rectangular and may have any suitable dimensions. The dicing of the sheet of piezoelectric material 110 may result in the pieces of piezoelectric material 220 having the same shape and dimensions or may be done so that difference pieces of piezoelectric material 220 have different shapes and/or dimensions.

FIG. 2C shows an example cross-sectional view of a sheet of piezoelectric material according to an implementation of the disclosed subject matter. The sheet of piezoelectric material 220 may be diced or laser cut through its thickness, so that the pieces of piezoelectric material 220 may be separable from each other.

FIG. 3A, FIG. 3B, and FIG. 3C show example pieces of piezoelectric material according to an implementation of the disclosed subject matter. The pieces of piezoelectric material 220 created by dicing or laser cutting the piece of piezoelectric material 110 may be separable from each other.

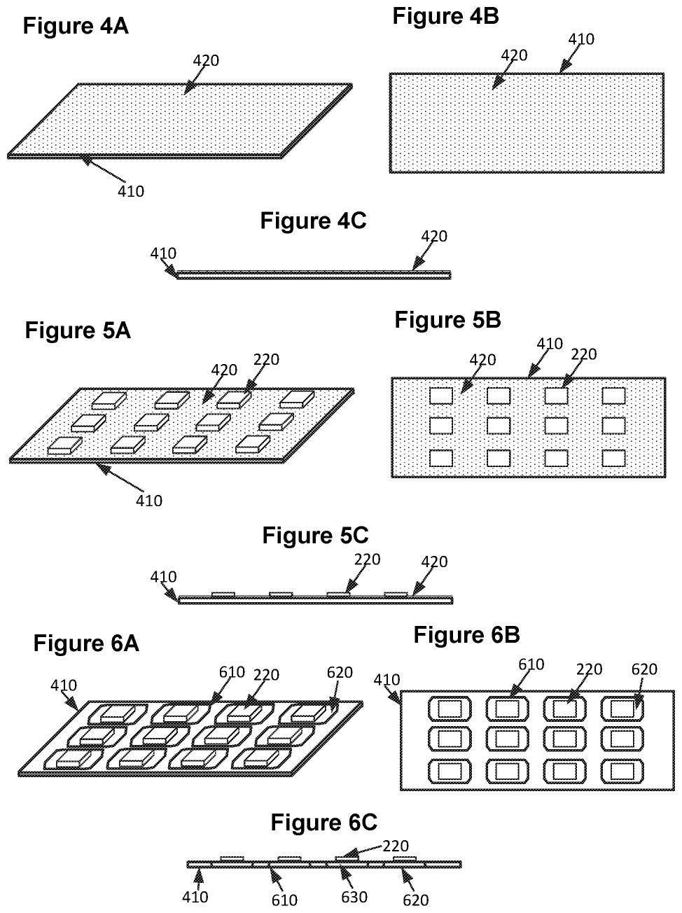

FIG. 4A shows an example sheet of elastic layer material according to an implementation of the disclosed subject matter. A sheet of elastic layer material 410 may be spin coated with adhesive 420 or adhesive film patterned. The sheet of elastic layer material 410 may be made of any suitable elastic material, such as, for example, iron-nickel alloys such as invar, aluminum, silicon, titanium, nickel, brass, steel, magnesium, or copper.

FIG. 4B shows an example sheet of elastic layer material according to an implementation of the disclosed subject matter. The sheet of elastic layer material 420 may have any suitable shape and any suitable dimensions. Spin coating or film transferring, using any suitable equipment, may be used to coat the sheet of elastic layer material 410 with the adhesive 420, which may be any suitable adhesive, such as, for example, an electrically conductive adhesive. The adhesive 420 may also be applied to the sheet of elastic layer material 410 as adhesive drops dispensed onto the sheet of elastic layer material 410.

FIG. 4C shows an example cross-sectional view of a sheet of elastic layer material according to an implementation of the disclosed subject matter. The sheet of elastic layer material 420 may have any suitable thickness. The thickness of the sheet of elastic layer material 410 may be the thickness needed to result in a transduction element of desired thickness when a piece of the piezoelectric material 220 is added to the sheet of elastic layer material 410. The adhesive 420 may coat a top surface of the sheet of elastic layer material 420. The adhesive 420 may not be used to coat the sides of bottom surface of the sheet of elastic layer material 420.

FIG. 5A shows an example sheet of elastic layer material with pieces of piezoelectric material according to an implementation of the disclosed subject matter. The pieces of piezoelectric material 220 may be placed onto the adhesive 420 on the sheet of elastic layer material 410.

FIG. 5B shows an example sheet of elastic layer material with pieces of piezoelectric material according to an implementation of the disclosed subject matter. The pieces of piezoelectric material 220 may be arranged on the sheet of elastic layer material 410 in any suitable pattern, and with any suitable spacing between the pieces of piezoelectric material 220. For example, the pieces of piezoelectric material 220 may be arranged in a grid pattern on the sheet of elastic layer material 410. Any suitable devices or equipment such as a stencil or pick and place machine may be used to place the pieces of piezoelectric material 220 onto the adhesive 420 on the sheet of elastic layer material 410.

FIG. 5C shows an example cross-sectional view of a sheet of elastic layer material with pieces of piezoelectric material according to an implementation of the disclosed subject matter. Pressure may be applied to the pieces of piezoelectric material 220 and sheet of elastic layer material 410 and the adhesive 420 may be cured. Pressure may be applied in any suitable manner, using any suitable equipment such as putting weights or applying pressure with a hydraulic piston. The adhesive 420 may be cured in any suitable manner for example in an oven at temperatures below the curie temperature of the piezoelectric material, for example, below 110 degrees Celsius. Pressure may be applied during curing process.

FIG. 6A shows an example sheet of elastic layer material with pieces of piezoelectric material according to an implementation of the disclosed subject matter. The sheet of elastic layer material 410 with the adhered pieces of piezoelectric material 220 may be laser-cut or chemically etched to create individual transduction elements 620. For example, laser-cutting or chemical etching may be used to cut the sheet of elastic layer material 410 along lines 610 into shapes around each of the pieces of the piezoelectric material adhered 220 to the sheet of elastic layer material 410.

FIG. 6B shows an example sheet of elastic layer material with pieces of piezoelectric material according to an implementation of the disclosed subject matter. The shapes laser-cut or chemically etched into the sheet of elastic layer material 410 may be any suitable shape, such as, for example, rectangles, irregular hexagons, or irregular octagons. The laser-cutting or chemical etching of the sheet of elastic layer material 410 may create individual transduction elements 620. A transduction element 620 may be a bimorph structure that may include a single piece of piezoelectric material 220 mounted on top of an elastic layer 630 that is a piece of the sheet of elastic layer material 410.

FIG. 6C shows an example cross-sectional view of a sheet of elastic layer material with pieces of piezoelectric material according to an implementation of the disclosed subject matter. The laser-cutting or chemical etching may go through the thickness of the sheet of elastic layer material 410 so that the transduction elements 620 are separable from the sheet of elastic layer material 410.

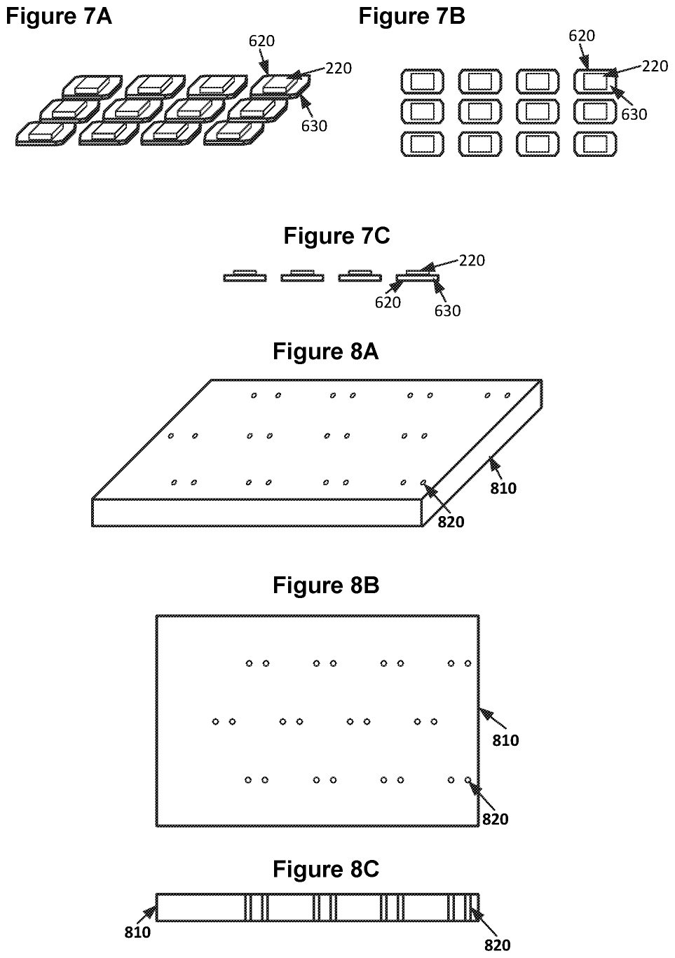

FIG. 7A, FIG. 7B, and FIG. 7C shows example transduction elements according to an implementation of the disclosed subject matter. The transduction elements 620 may each include a piece of piezoelectric material 220 adhered to an elastic layer 630 that may be a piece of the sheet of elastic layer material 410. The transduction elements 620 may be separated from the remainder of the sheet of elastic layer material 410.

FIG. 8A shows an example PCB mounting board according to an implementation of the disclosed subject matter. A PCB mounting board 810 may be prepared with electrical vias 820 and traces on its top and bottom sides. For example, the PCB mounting board 810 may be prepared with electrical vias 820 and traces that may be able to provide electrical connections for multiple transduction elements 620. The PCB mounting board 810 may have two vias for every transduction element 620 that will be attached to the PCB mounting board 810.

FIG. 8B shows an example PCB mounting board according to an implementation of the disclosed subject matter. Electrical contacts for the vias 820 may be arranged in any suitable pattern on the top surface of the PCB mounting board 810. For example, the electrical contacts for the vias 820 may be arranged so that the transduction elements 620 may be attached to the PCB mounting board 810 in a hexagonal pattern with each transduction element 620 in contact with one of the electrical contacts for one of the vias 820.

FIG. 8C shows an example cross-sectional view of a PCB mounting board according to an implementation of the disclosed subject matter. The vias 820 may go through the thickness of PCB mounting board 810, which may have any suitable number of layers. The vias 820 may be routed straight down through the thickness of the PCB mounting board 810, or alternatively may be redirected through traces on inner layers of the PCB mounting board 810.

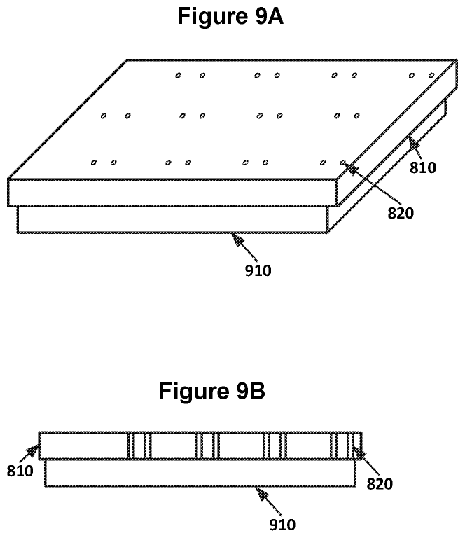

FIG. 9A shows an example PCB mounting board and electronics according to an implementation of the disclosed subject matter. Electronics 910 may be mounted on the back side of the PCB mounting board 810. The electronics 910 may be, for example, drivers, rectifiers, voltage regulators, or other electronic devices use to provide power to, receive power from, and control the transduction elements 620. The electronics 910 may be mounted as discrete components or may be in the form of ASICs or other integrated circuits and may be packaged in any suitable manner.

FIG. 9B shows an example PCB mounting board and electronics according to an implementation of the disclosed subject matter. The electronics 910 may be attached to the PCB mounting board 810 and connected to electrical contacts for the vias 820 in any suitable manner. For example, the electronics 910 may be soldered to electrical contacts for the vias 820 on the back side of the PCB mounting board 910, electrically connecting the electronics 910 to electrical contacts for the vias 820 on the front side of the PCB mounting board 910.

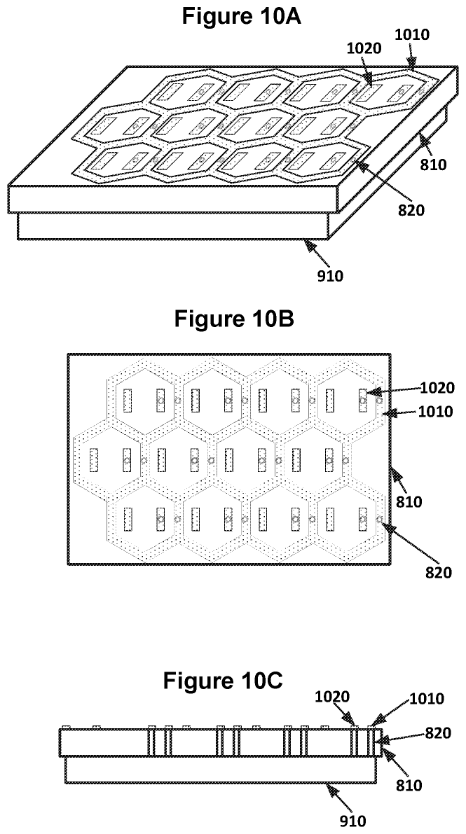

FIG. 10A shows an example PCB mounting board and electronics according to an implementation of the disclosed subject matter. Adhesives 1010 and 1020 may be applied onto the top side of the PCB mounting board 810. The adhesives 1010 and 1020 may be any suitable electrically conductive adhesives and may be screen printed or film patterned using any suitable screen-printing or film transfer techniques and equipment. The adhesives 1010 and 1020 may be the same type of adhesive, or may be different types of adhesive.

FIG. 10B shows an example PCB mounting board and electronics according to an implementation of the disclosed subject matter. The conductive adhesives 1010 and 1020 may be screen printed or film patterned onto the top of the PCB mounting board 810 in any suitable pattern. For example, the adhesives 1010 and 1020 may be screen printed or film patterned so that each of the vias 820 of the PCB mounting board 810 may be covered with adhesive 1010 or the adhesive 1020 while not creating an electrical connection between any two of the vias 820 through the adhesive 1010 and the adhesive 1020. The adhesive 1020 may be screen printed or film patterned so that a transduction element 620 may be placed with one end of the transduction element 620 on adhesive 1020 covering a via 820 and the other end of the transduction element 620 on adhesive 1020 that is not covering a via 820. The adhesive 1010 may be screen printed or film patterned to allow a spacer to be adhered to the PCB mounting board 810 around the transduction elements 620.

FIG. 10C shows an example cross-sectional view of a PCB mounting board and electronics according to an implementation of the disclosed subject matter. The adhesive 1010 and the adhesive 1020 may cover each of the vias 820 on the top surface of the PCB mounting board 810, creating an electrical connection between the electronics 910 and the adhesive 1010 and the adhesive 1020.

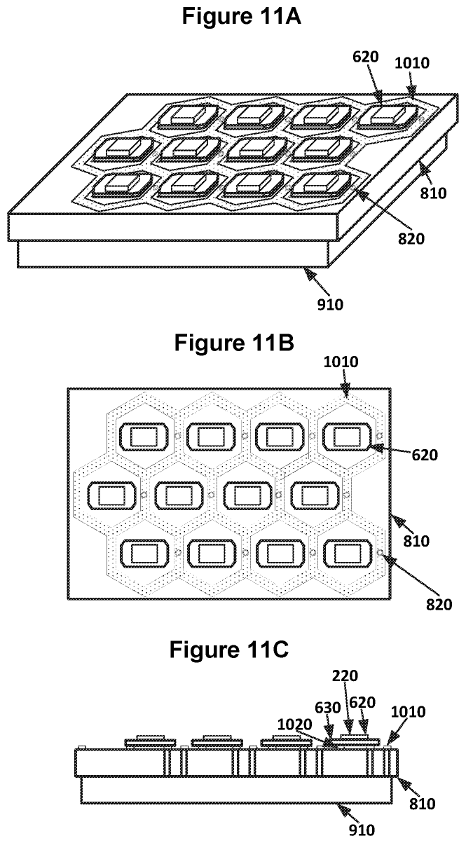

FIG. 11A shows an example PCB mounting board, electronics, and transduction elements according to an implementation of the disclosed subject matter. The transduction elements 620 may be mounted on the PCB mounting board 810. The transduction elements 620 may be mounted on the PCB mounting board 810 by placing the transduction elements 620 directly onto the adhesive 1020 screen printed or film patterned on top surface of the PCB mounting board 810.

FIG. 11B shows an example PCB mounting board, electronics, and transduction elements according to an implementation of the disclosed subject matter. The transduction elements 620 may be mounted on the PCB mounting board 810 in any suitable pattern. For example, the transduction elements 620 may be mounted in a hexagonal tiling pattern, which may be based on the pattern in which the adhesive 1010 was screen printed or film patterned on to the top surface of the PCB mounting board 810.

FIG. 11C shows an example cross-sectional view of a PCB mounting board, electronics, and transduction elements. The transduction elements 620 may be placed on the PCB mounting board 810 with the elastic layer 630 in contact with the adhesive 1020. Parts of the elastic layer 630 not in contact with the adhesive 1020 may be above the top surface of the PCB mounting board 810, with an airgap between the top surface of the PCB mounting board 810 and the elastic layer 630 of the transduction element 620. Each transduction element 620 may be placed so that one end of the transduction element 620 is placed on the adhesive 1020 covering a via 820 on the PCB mounting board and the other end is placed on the adhesive 1020 that does not cover a via 820.

In some implementations, standoffs may be mounted between transduction elements 620 and the PCB mounting board 810. A standoff, which may be made of any suitable electrically conductive material, may be placed on adhesive 1020 on the PCB mounting board 810, and may have adhesive applied to the top side of the standoff. A transduction element 620 may be placed on the adhesive on the top side of the standoff. Standoffs may be used to adjust the height of the transduction elements 620 relative to the PCB mounting board 810.

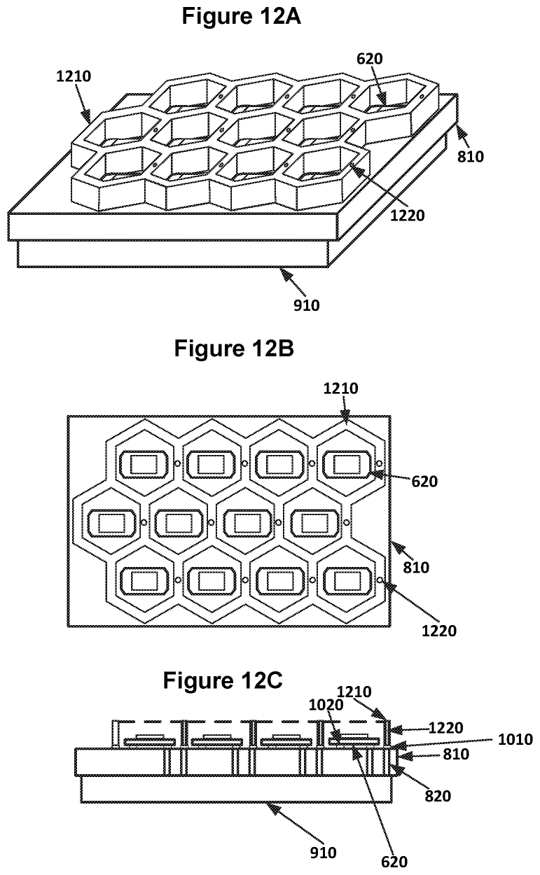

FIG. 12A shows an example PCB mounting board, electronics, transduction elements, and spacer according to an implementation of the disclosed subject matter. A spacer 1210 may be mounted on the PCB mounting board 810. The spacer 1210 may be made of an electrically conductive material or may be made of a non-electrically conductive material and may have vias 1220. The transduction elements 620 may be surrounded by the spacer 1210.

FIG. 12B shows an example PCB mounting board, electronics, transduction elements, and spacer according to an implementation of the disclosed subject matter. The spacer 1210 may have any suitable shape and pattern. For example, the spacer 1210 may be walls around empty cells in a hexagonal tiling pattern. Each empty cell of the spacer 1210 may be of a suitable size to fit around a transduction element 620. The spacer 1210 may be placed on the PCB mounting board 810 so that all, or portions, of the bottom of the walls of the spacer 1210 are on the adhesive 1010 on the PCB mounting board 810, including adhesive 1010 that covers the vias 820 that are not covered by the transduction elements 620. In some implementations, the adhesive 1010 may be applied to the bottom of the spacer 1210 instead of to the PCB mounting board 810. The adhesive 1010 on the bottom of the spacer 1210 may be used to attach the spacer 1210 to the PCB mounting board 810.

FIG. 12C shows an example cross-sectional view of a PCB mounting board, electronics, transduction elements, and spacer. If the spacer 1210 is made of a non-electrically conductive material, vias 1220 in the spacer may be aligned with the vias 820 that are not covered by the transduction elements 620. The vias 1220 may be electrically connected to the vias 820 by, for example, the adhesive 1010. Walls of the spacer 1210 that do not cover one of the vias 820 may not include a via 1220. The walls of the spacer may be of any suitable height, and may, for example, be taller than transduction elements 620.

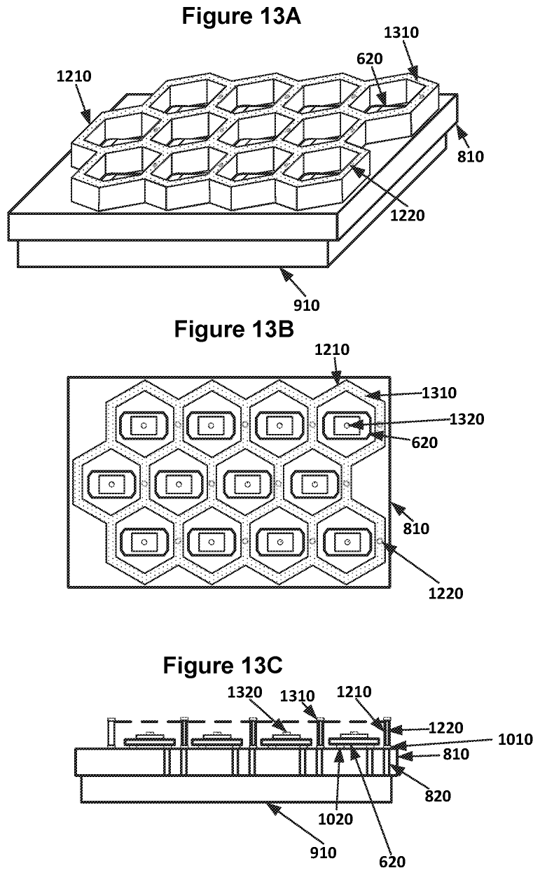

FIG. 13A shows an example PCB mounting board, electronics, transduction elements, and spacer according to an implementation of the disclosed subject matter. Adhesive 1310 may be screen printed or film patterned on top of the spacer 1210, and adhesive 1320 may be screen printed or film patterned at the centers of the tops of the transduction elements 620. The adhesives 1310 and 1320 may be any suitable electrically conductive adhesive, and may be the same adhesive type or may be different adhesive types.

FIG. 13B shows an example PCB mounting board, electronics, transduction elements, and spacer according to an implementation of the disclosed subject matter. The adhesive 1310 may be screen printed or film patterned onto the top of the walls of the spacer 1210. The adhesive 1310 may cover the vias 1210. The adhesive 1320 may also be screen printed or film patterned at the centers of the tops of the transduction elements 620. The adhesives 1310 and 1320 may be screen printed or film patterned using any suitable screen-printing or film transfer techniques and equipment.

FIG. 13C shows an example cross-sectional view of a PCB mounting board, electronics, transduction elements, and spacer. The adhesive 1310 may be screen printed or film patterned to cover the entirety of the top of the walls of the spacer 1210 or may be printed in any other suitable pattern onto the top of the walls of the spacer 1210.

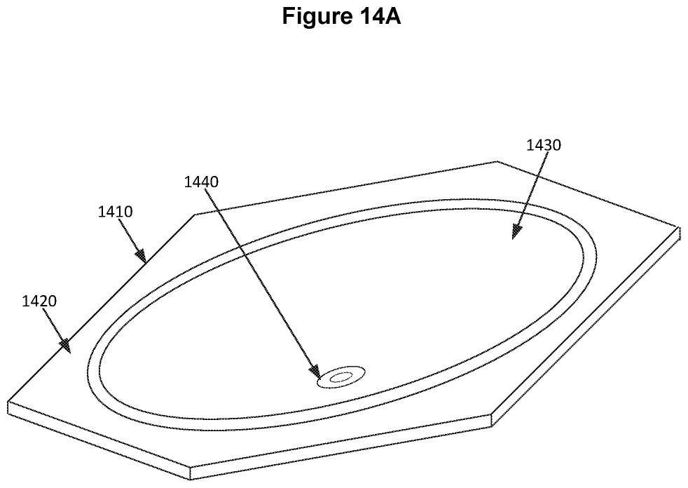

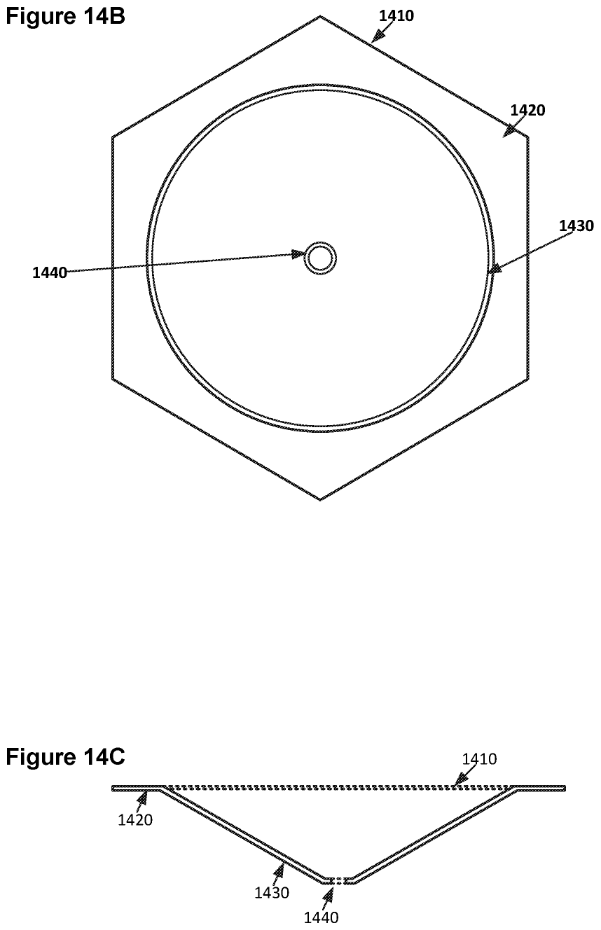

FIG. 14A shows an example diaphragm according to an implementation of the disclosed subject matter. A diaphragm 1410 may be made of any suitable electrically conductive material, such as, for example, aluminum. The diaphragm 1410 may be in any suitable shape, such as, for example, a cup or bowl shape. The diaphragm 1410 may include a perimeter 1420, which may be any suitable shape, such as, for example hexagonal. The diaphragm 410 may include a cup 1430. The bottom of the cup 1430 may include a cutout 1440. In some implementations, the perimeter 1420 may include cutouts surrounding the circumference of the cup. The cutouts may be holes of any suitable shape in the perimeter 1420.

FIG. 14B shows an example diaphragm according to an implementation of the disclosed subject matter. The cutout 1440 may be at the center of the cup 1430 of the diaphragm 1410.

FIG. 14C shows an example cross-sectional view of a diaphragm according to an implementation of the disclosed subject matter. The cup 1430 may be a cup or bowl-shaped portion of the diaphragm 1410 of any suitable depth and with any suitable curvature from the top of the diaphragm 1410 to the cutout 1440. The cutout 1440 may be located on a flattened section of the cup 1430 centered at the bottom of the cup 1430.

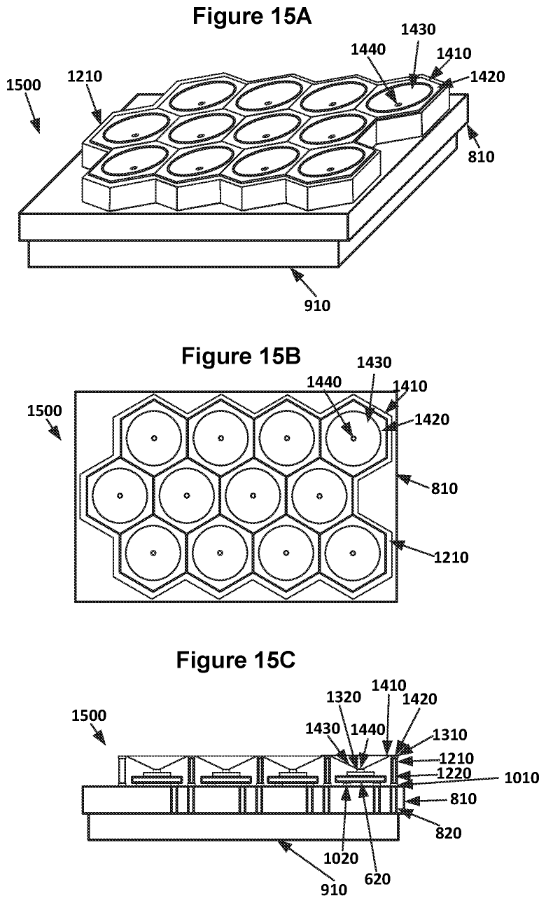

FIG. 15A shows an example piezoelectric transducer array according to an implementation of the disclosed subject matter. The diaphragms 1410 may be mounted on to the spacer 1210 and the transduction elements 620. The diaphragms 1410 may be mounted on to the adhesive 1310 on the top of the walls of the spacer 1210. The perimeters 1420 of the diaphragms 1410 may be adhered to the walls on the top of the spacer 1210 by the adhesive 1310. Adhering the diaphragms 1410 to the spacer 1210 may complete the fabrication of piezoelectric transducer array 1500. Each diaphragm 1410 and transducer element 620 may form a single piezoelectric transducer of the piezoelectric transducer array 1500. In some implementations, the diaphragms 1410 may be mounted on the spacer 1210 before the spacer 1210 is mounted on the PCB mounting board 810.

FIG. 15B shows an example piezoelectric transducer array according to an implementation of the disclosed subject matter. The diaphragms 1410 may each cover a transducer 620. The diaphragms 1410 may be arranged so that there is little or no gap between the perimeters 1420 of neighboring diaphragms 1410. In some implementations, instead of being separate components, multiple diaphragms 1410 may be part of a single integral component with multiple cups 1430 and multiple perimeters 1420 arranged in any suitable pattern to fit onto the spacer 1210.

FIG. 15C shows an example cross-sectional view of a piezoelectric transducer array according to an implementation of the disclosed subject matter. The centers of the diaphragms 1410, which may be the cutouts 1440 in the cups 1430, may be mounted on to the adhesive 1320 at the center of transduction elements 620. This may create a mechanical connection between the transduction elements 620 and the diaphragms 1410 so that, for example, flexure of a piece of piezoelectric material 220 may cause movement of the diaphragm 1410 adhered to that piece of piezoelectric material, and movement of the diaphragm 1410 due to forces such as, for example, sound waves, may cause flexure of the piece of piezoelectric material 220 to which the diaphragm 1410 is adhered.

The adhesives 1310 and 1320 may also create an electrical connection between the diaphragms 1410 and the transduction elements 620. This may allow the electronics 910 to control the piezoelectric transducer array 1500, for example, sending electrical signals to the transducer elements 620 to cause movement of the diaphragms 1410 and generation of sound waves, including ultrasonic sound waves. Movement of the diaphragms 1410 by forces such as sound waves impacting the cups 1430 of the diaphragms 1410 may cause flexure of the transduction elements 620, resulting in the pieces of piezoelectric material 220 generating an electrical voltage that may be used by the electronics 910 in any suitable manner. For example, the electronics 910 may be connected to any suitable power source, power storage, and/or electrical load.

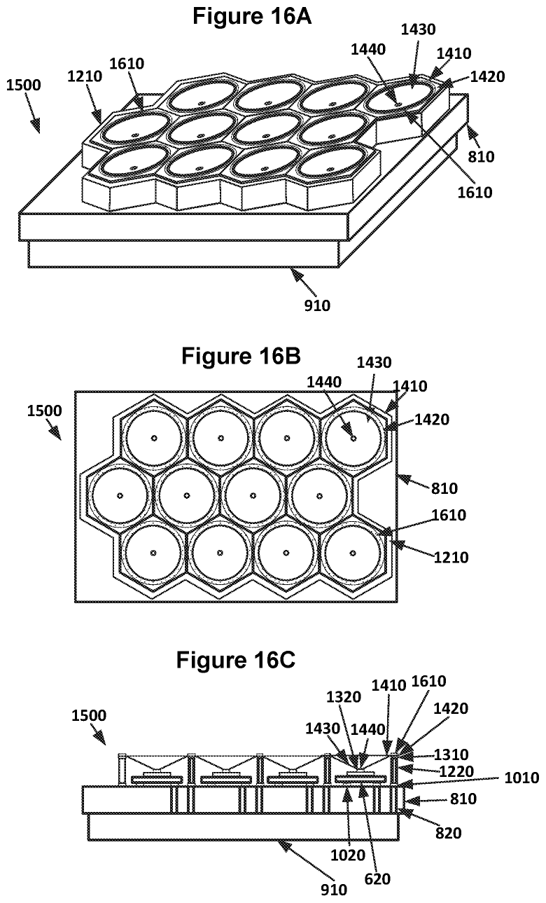

FIG. 16A shows an example piezoelectric transducer array according to an implementation of the disclosed subject matter. Adhesive 1610 may be applied on the top sides of the diaphragms 1410. For example, any suitable electrically conductive adhesive may be screen printed or film patterned onto the perimeters 1420 of the diaphragms 1410 using any suitable screen-printing or film transfer techniques and equipment.

FIG. 16B shows an example piezoelectric transducer array according to an implementation of the disclosed subject matter. The adhesive 1610 may be screen printed or film patterned to cover the entirety of the perimeters 1420 of the diaphragms 1410 or may be printed in any other suitable pattern onto the perimeters 1420 of the diaphragms 1410. The adhesive 1610 may, for example, encircle each of the cups 1430 of the diaphragms 1410. If the diaphragms 1410 are spaced out from each other, the top side of spacer 1210 ay be screen printed or film patterned with adhesive 1610.

FIG. 16C shows an example cross-sectional view of a piezoelectric transducer array according to an implementation of the disclosed subject matter. The adhesive 1610 may be on top of the perimeters 1420 of the diaphragms 1410 and may be aligned with top of the walls of the spacer 1210.

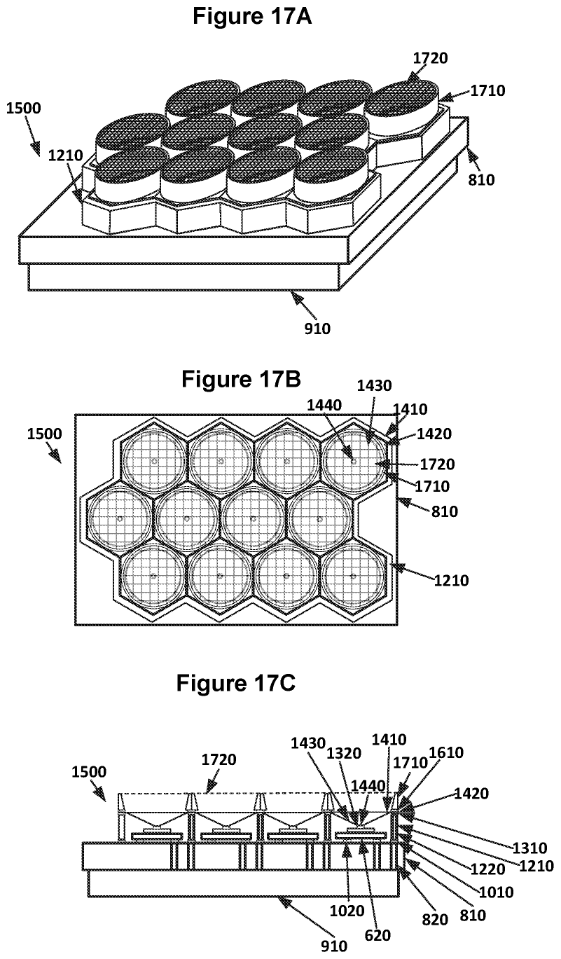

FIG. 17A shows an example piezoelectric transducer array according to an implementation of the disclosed subject matter. Waveguides 1710 and protection grids 1720 may be mounted on top of the diaphragms 1410. The waveguides 1710 may be attached to the diaphragms 1410 by the adhesive 1610 screen printed or film patterned on the perimeters 1420 of the diaphragms 1410, or onto the spacer 1210. The protection grids 1720 may be attached to the top of the waveguides 1710. The waveguides 1710 and protection grids 1720 may be made from any suitable materials, such as, for example, plastics, silicones, papers, cloths, fiberglass, carbon fiber, or polymers generally.

FIG. 17B shows an example piezoelectric transducer array according to an implementation of the disclosed subject matter. The waveguides 1710 may have any suitable shape. For example, the waveguides 1710 may be rings or hexagonal with walls of a tapered thickness that may be thicker at the base of the waveguides 1710 and thinner at the top of the waveguides 1710. The waveguides 1710 may encircle the cups 1430 of the diaphragms 1410. The protection grids 1720 may be grids of any suitable type and grid pattern, with any suitable grid density.

The waveguides 1720 for the piezoelectric transducer array 1500 may be separate components or may be part of a single waveguide component. A single waveguide component may be multiple waveguides 1720 connected together in a pattern that may align with the perimeters 1420 of the diaphragms 1410 of the piezoelectric transducer array 1500. The single waveguide component may have multiple protections grids 1720, for example, one for each diaphragm 1410 that will be encircled by the walls of the waveguide component, or may have a single protection grid 1720 that may cover all of the diaphragms 1410.

FIG. 17C shows an example cross-sectional view of a piezoelectric transducer array according to an implementation of the disclosed subject matter. The walls of the waveguides 1710 may be tapered and may be thicker at the base where the waveguides 1720 are attached to the perimeters 1420 of the diaphragms 1410 by the adhesive 1610, and thinner at the top where the protection grids 1720 are attached. The protection grids 1720 may cover the cups 1430 of the diaphragms 1410. This may protect the cups 1430 from foreign objects while still allowing coupling between the cups 1430 and a transmission medium, such as, for example, air.

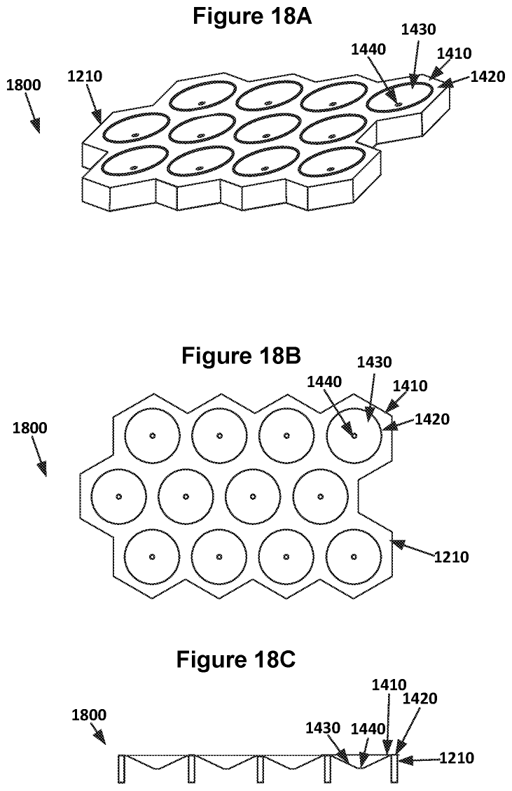

FIG. 18A shows an example single component spacer and diaphragm according to an implementation of the disclosed subject matter. In some implementations, the diaphragms 1410 and the spacer 1210 may be a single component. A spacer/diaphragm component 1800 may include the diaphragms 1410 and the spacer 1210 combined into a single integral component. The spacer/diaphragm component 1800 may be made of any suitable material, such as an electrically conductive material.

FIG. 18B shows an example single component spacer and diaphragm according to an implementation of the disclosed subject matter. The top of the walls of the spacer 1210 may serve as the perimeters 1420 of the diaphragms 1410 in the spacer/diaphragm component 1800.

FIG. 18C shows an example cross-sectional view of a single component spacer and diaphragm according to an implementation of the disclosed subject matter. The spacer/diaphragm component 1800 may not include vias, as the spacer spacer/diaphragm component 1800 may be made of an electrically conductive material.

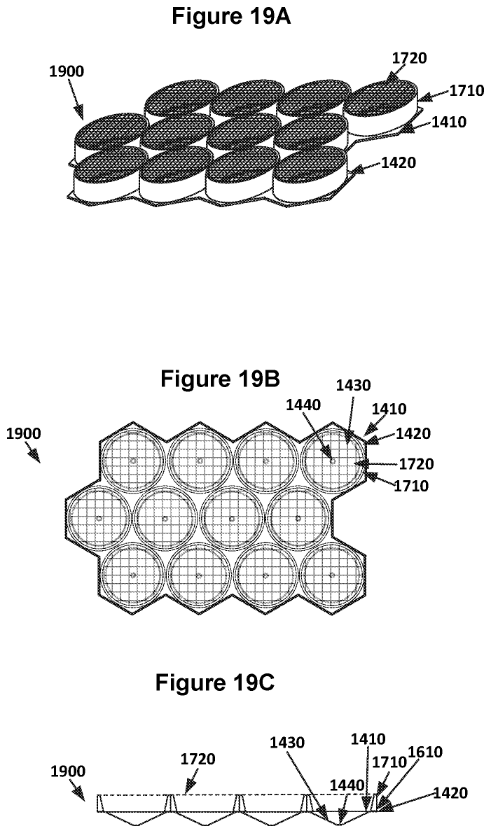

FIG. 19A shows an example single component diaphragm and waveguide according to an implementation of the disclosed subject matter. In some implementations, the diaphragms 1410 and the waveguides 1710 may be a single piece. A diaphragm/waveguide component 1900 may include the diaphragms 1410 and the waveguides 1710 combined into a single integral component. The diaphragm/waveguide component 1900 may be made of any suitable material, such as an electrically conductive material. The diaphragm/waveguide component 1900 may also include the protection grid 1720 mounted at the top of the waveguides 1710 of the diaphragm/waveguide component 1900.

FIG. 19B shows an example piezoelectric transducer array according to an implementation of the disclosed subject matter. The perimeters 1420 of the diaphragms 1410 may serve as the base of the waveguides 1710 in the diaphragm/waveguide component 1900.

FIG. 19C shows an example cross-sectional view of a piezoelectric transducer array according to an implementation of the disclosed subject matter. The protection grid 1720 may cover the cups 1430 of the diaphragms 1410 of the diaphragm/waveguide component 1900.

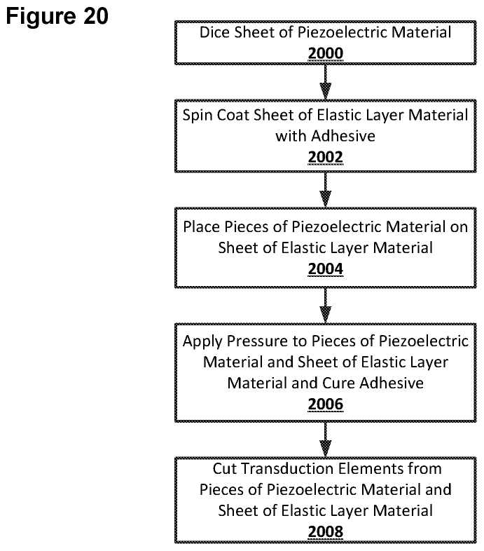

FIG. 20 shows an example procedure suitable for piezoelectric transducer array fabrication according to an implementation of the disclosed subject matter. At 2000, a sheet of piezoelectric material may be diced. For example, the sheet of piezoelectric material 110 may be diced or laser-cut in any suitable manner, using any suitable equipment or devices, to produce pieces of piezoelectric material 220. The pieces of piezoelectric material 220 may be rectangular and may have any suitable dimensions. The dicing of the sheet of piezoelectric material 110 may result in the pieces of piezoelectric material 220 having the same shape and dimensions or may be done so that difference pieces of piezoelectric material 220 have different shapes and/or dimensions.

At 2002, a sheet of elastic layer material may be spin coated with adhesive. For example, the sheet of elastic layer material 410 may be spin coated with the adhesive 420 using any suitable equipment or devices. The sheet of elastic layer material 410 may be made of any suitable elastic material, such as, for example, iron-nickel alloys such as invar. The adhesive 420 may coat a top surface of the sheet of elastic layer material 410. In some implementations, the adhesive 420 may also be applied to the sheet of elastic layer material 410 as adhesive drops dispensed onto the sheet of elastic layer material 410 or as adhesive film transferred to the elastic layer material 410.

At 2004, pieces of piezoelectric material may be placed onto the sheet of elastic layer material. For example, the pieces of piezoelectric material 220 may be placed onto the adhesive 420 on the sheet of elastic layer material 410. The pieces of piezoelectric material 220 may be arranged on the sheet of elastic layer material 410 in any suitable pattern, and with any suitable spacing between the pieces of piezoelectric material 220. For example, the pieces of piezoelectric material 220 may be arranged in a grid pattern on the sheet of elastic layer material 410. Any suitable devices or equipment may be used to place the pieces of piezoelectric material 220 onto the adhesive 420 on the sheet of elastic layer material 410.

At 2006, pressure may be applied to the pieces of piezoelectric material and the sheet of elastic layer material and the adhesive may be cured. For example, pressure may be applied to the pieces of piezoelectric material 220 and sheet of elastic layer material 410 and the adhesive 420 may be cured. Pressure may be applied in any suitable manner, using any suitable equipment. The adhesive 420 may be cured in any suitable manner.

At 2008, transduction elements may be cut from the pieces of piezoelectric material and the sheet of elastic layer material. For example, the sheet of elastic layer material 410 with the adhered pieces of piezoelectric material 220 may be laser-cut or chemically etched to create individual transduction elements 620. For example, laser-cutting or chemical etching may be used to cut the sheet of elastic layer material 410 along lines 610 into shapes around each of the pieces of the piezoelectric material adhered 220 to the sheet of elastic layer material. The shapes laser-cut or chemically etched into the sheet of elastic layer material 410 may be any suitable shape, such as, for example, rectangles, irregular hexagons, or irregular octagons. The laser-cutting or chemical etching of the sheet of elastic layer material 410 may create individual transduction elements 620. A transduction element 620 may be a bimorph structure that may include a single piece of piezoelectric material 220 mounted on top of an elastic layer 630 that is a piece of the sheet of elastic layer material 410. The transduction elements 620 may be separable from each other and from any remainder of the sheet of elastic layer material 410.

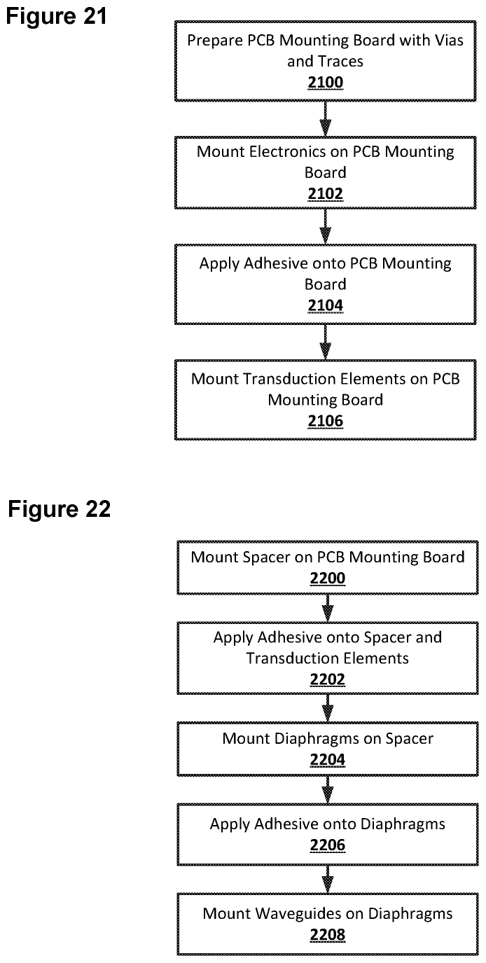

FIG. 21 shows an example procedure suitable for piezoelectric transducer array fabrication according to an implementation of the disclosed subject matter. At 2100, a PCB mounting board may be prepared with vias and traces. For example, the PCB mounting board 810 may be prepared with electrical vias 820 and traces on its top and bottom sides that may be able to provide electrical connections for multiple transduction elements 620. The PCB mounting board 810 may have two vias for every transduction element 620 that will be attached to the PCB mounting board 810. Electrical contacts for the vias 820 may be arranged in any suitable pattern on the top surface of the PCB mounting board 810. For example, the electrical contacts for the vias 820 may be arranged so that the transduction elements 620 may be attached to the PCB mounting board 810 in a hexagonal pattern with each transduction element 620 in contact with one of the electrical contacts. The vias 820 may go through the thickness of PCB mounting board 810, which may have any suitable number of layers. The vias 820 may be routed straight down through the thickness of the PCB mounting board 810, or alternatively may be redirected through traces on inner layers of the PCB mounting board 810.

At 2102, electronics may be mounted on the PCB mounting board. For example, the electronics 910 may be mounted on the back side of the PCB mounting board 810. The electronics 910 may be, for example, drivers, rectifiers, or other electronic devices use to provide power to, receive power from, and control the transduction elements 620. The electronics 910 may be mounted as discrete components or may be in the form of ASICs or other integrated circuits and may be packaged in any suitable manner. The electronics 910 may be attached to the PCB mounting board 810 and connected to electrical contacts for the vias 820 in any suitable manner. For example, the electronics 910 may be soldered to electrical contacts for the vias 820 on the back side of the PCB mounting board 910, electrically connecting the electronics 910 to electrical contacts for the vias 820 on the front side of the PCB mounting board 910.

At 2104, adhesive may be applied onto the PCB mounting board. For example, the adhesive 1010 and the adhesive 1020 may screen printed or film patterned onto the top side of the PCB mounting board 810. The adhesive 1010 and the adhesive 1020 may be any suitable electrically conductive adhesive and may be screen printed or film patterned using any suitable screen-printing film transfer techniques and equipment. The adhesive 1010 and the adhesive 1020 may be the same type of adhesive, or may be different types of adhesive. The conductive adhesive 1010 and the adhesive 1020 may be screen printed or film patterned onto the top of the PCB mounting board 810 in any suitable pattern. For example, the adhesive 1010 and the adhesive 1020 may be screen printed or film patterned so that each of the vias 820 of the PCB mounting board 810 may be covered with adhesive 1010 or the adhesive 1020 while not creating an electrical connection between any two of the vias 820 through the adhesive 1010 and the adhesive 1020. The adhesive 1020 may be screen printed or film patterned so that a transduction element 620 may be placed with one end of the transduction element 620 on adhesive 1020 covering a via 820 and the other end of the transduction element 620 on adhesive 1020 that is not covering a via 820. The adhesive 1010 may be screen printed or film patterned to allow the spacer 1210 to be adhered to the PCB mounting board 810 around the transduction elements 620. The adhesive 1010 and the adhesive 1020 may cover each of the vias 820 on the top surface of the PCB mounting board 810, creating an electrical connection between the electronics 910 and the adhesive 1010 and the adhesive 1020.

At 2106, transduction elements may be mounted on the PCB mounting board. For example, the elements 620 may be mounted on the PCB mounting board 810. The transduction elements 620 may be mounted on the PCB mounting board 810 by placing the transduction elements 620 directly onto the adhesive 1020 screen printed or film patterned on top surface of the PCB mounting board 810. The transduction elements 620 may be mounted on the PCB mounting board 810 in any suitable pattern. For example, the transduction elements 620 may be mounted in a hexagonal tiling pattern, which may be based on the pattern in which the adhesive 1020 was screen printed or film patterned on to the top surface of the PCB mounting board 810. The transduction elements 620 may be placed on the PCB mounting board 810 the elastic layer 630 in contact with the adhesive 1020. Each transduction element 620 may be placed so that one end of the transduction element 620 is placed on the adhesive 1020 covering a via 820 on the PCB mounting board and the other end is placed on adhesive 1020 that does not cover a via 820.

FIG. 22 shows an example procedure suitable for piezoelectric transducer array fabrication according to an implementation of the disclosed subject matter. At 2200, a spacer may be mounted on the PCB mounting board. For example, the spacer 1210 may be mounted on the PCB mounting board 810. The spacer 1210 may be made of an electrically conductive material or may be made of a non-electrically conductive material and may have vias 1220. The transduction elements 620 may be surrounded by the spacer 1210. The spacer 1210 may have any suitable shape and pattern. For example, the spacer 1210 may be walls around empty cells in a hexagonal tiling pattern. Each empty cell of the spacer 1210 may be of a suitable size to fit around a transduction element 620. The spacer 1210 may be placed on the PCB mounting board 810 so that all, or portions, of the bottom of the walls of the spacer 1210 are on the adhesive 1010 on the PCB mounting board 810, including adhesive 1010 that covers the vias 820 that are not covered by the transduction elements 620. If the spacer 1210 is made of a non-electrically conductive material, vias 1220 in the spacer may be aligned with the vias 820 that are not covered by the transduction elements 620. The vias 1220 may be electrically connected to the vias 820 by, for example, the adhesive 1010. Walls of the spacer 1210 that do not cover one of the vias 820 may not include a via 1220. The walls of the spacer may be of any suitable height, and may, for example, be taller than transduction elements 620.

At 2202, adhesive may be applied on the spacer and transduction elements. For example, the adhesive 1310 may be screen printed or film patterned on top of the spacer 1210 and the adhesive 1320 may be screen printed or film patterned at the centers of the tops of the transduction elements 620. The adhesive 1310 may be any suitable electrically conductive adhesive. The adhesive 1310 may be screen printed or film patterned onto the top of the walls of the spacer 1210. The adhesive 1310 may cover the vias 1210. The adhesive 1320 may be screen printed or film patterned at the centers of the tops of the transduction elements 620. The adhesives 1310 and 1320 may be screen printed or film patterned using any suitable screen-printing techniques and equipment. The adhesive 1310 may be screen printed or film patterned to cover the entirety of the top of the walls of the spacer 1210, or may be printed or film patterned in any other suitable pattern onto the top of the walls of the spacer 1210.

At 2204, diaphragms may be mounted on the spacer. For example, the diaphragms 1410 may be mounted on to the spacer 1210 and the transduction elements 620. The diaphragms 1410 may be mounted on to the adhesive 1310 on the top of the walls of the spacer 1210. The perimeters 1420 of the diaphragms 1410 may be adhered to the walls on the top of the spacer 1210 by the adhesive 1310. Adhering the diaphragms 1410 to the spacer 1210 may complete the fabrication of piezoelectric transducer array 1500. Each diaphragm 1410 and transducer element 620 may form a single piezoelectric transducer of the piezoelectric transducer array 1500. The diaphragms 1410 may each cover a transducer 620. The diaphragms 1410 may be arranged so that there is little or no gap between the perimeters 1420 of neighboring diaphragms 1410. In some implementations, instead of being separate components, multiple diaphragms 1410 may be part of a single integral component with multiple cups 1430 and multiple perimeters 1420 arranged in any suitable pattern to fit onto the spacer 1210. The centers of the diaphragms 1410, which may be the cutouts 1440 in the cups 1430, may be mounted on to the adhesive 1320 at the center of transduction elements 620. This may create a mechanical connection between the transduction elements 620 and the diaphragms 1410 so that, for example, flexure of a piece of piezoelectric material 220 may cause movement of the diaphragm 1410 adhered to that piece of piezoelectric material, and movement of the diaphragm 1410 due to forces such as, for example, sound waves, may cause flexure of the piece of piezoelectric material 220 to which the diaphragm 1410 is adhered.

At 2206, adhesive may be applied onto the diaphragms. For example, the adhesive 1610 may be any suitable electrically adhesive which may be screen printed or film patterned on the top sides of the diaphragms 1410 on the perimeters 1420 of the diaphragms 1410 using any suitable screen-printing or film transfer techniques and equipment. The adhesive 1610 may be screen printed or film patterned to cover the entirety of the perimeters 1420 of the diaphragms 1410 or may be printed in any other suitable pattern onto the perimeters 1420 of the diaphragms 1410. The adhesive 1610 may, for example, encircle each of the cups 1430 of the diaphragms 1410. The adhesive 1610 may be on top of the perimeters 1420 of the diaphragms 1410 and may be aligned with top of the walls of the spacer 1210.

At 2208, waveguides may be mounted on the diaphragms. For example, the waveguides 1710 and protection grids 1720 may be mounted on top of the diaphragms 1410. The waveguide 1710s may be attached to the diaphragms 1410 by the adhesive 1610 screen printed or film patterned on the perimeters 1420 of the diaphragms 1410. The protection grids 1720 may be attached to the top of the waveguides 1710. The waveguides 1710 and protection grids 1720 may be made from any suitable materials, such as, for example, plastics, silicones, papers, cloths, fiberglass, carbon fiber, or polymers generally. The waveguides 1710 may have any suitable shape. For example, the waveguides 1710 may be rings with walls of a tapered thickness that may be thicker at the base of the waveguides 1710 and thinner at the top of the waveguides 1710. The waveguides 1710 may encircle the cups 1430 of the diaphragms 1410. The protection grids 1720 may be grids of any suitable type and grid pattern, with any suitable grid density. The waveguides 1720 for the piezoelectric transducer array 1500 may be separate components or may be part of a single waveguide component. A single waveguide component may be multiple waveguides 1720 connected together in a pattern that may align with the perimeters 1420 of the diaphragms 1410 of the piezoelectric transducer array 1500. The single waveguide component may have multiple protections grids 1720, for example, one for each diaphragm 1410 that will be encircled by the walls of the waveguide component or may have a single protection grid 1720 that may cover all of the diaphragms 1410. The walls of the waveguides 1710 may be tapered and may be thicker at the base where the waveguides 1720 are attached to the perimeters 1420 of the diaphragms 1410 by the adhesive 1610, and thinner at the top where the protection grids 1720 are attached. The protection grids 1720 may cover the cups 1430 of the diaphragms 1410. This may protect the cups 1430 from foreign objects while still allowing coupling between the cups 1430 and a transmission medium, such as, for example, air.

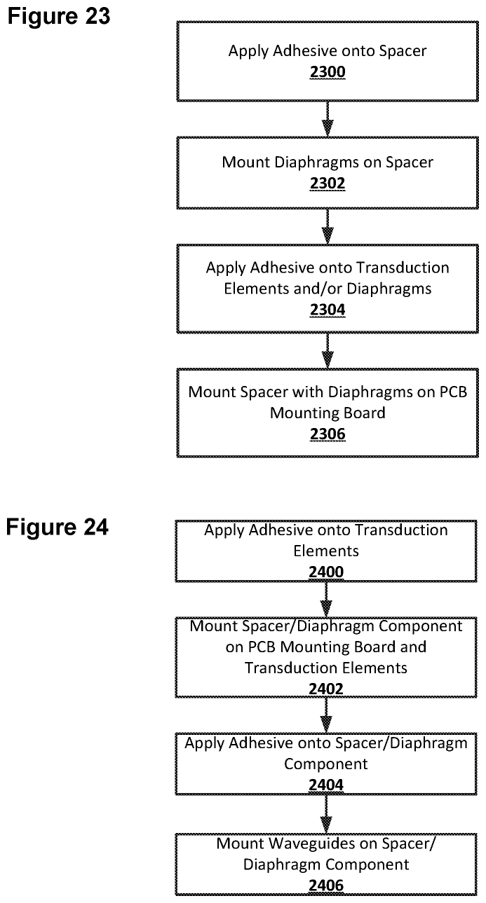

FIG. 23 shows an example procedure suitable for piezoelectric transducer array fabrication according to an implementation of the disclosed subject matter. At 2300, adhesive may be applied on a spacer. For example, the adhesive 1310 may be screen printed or film patterned on top of the spacer 1210. The adhesive 1310 may be any suitable electrically conductive adhesive. The adhesive 1310 may be screen printed or film patterned onto the top of the walls of the spacer 1210. The adhesive 1310 may cover the vias 1210. The adhesive 1310 may be screen printed or film patterned using any suitable screen-printing or film transfer techniques and equipment. The adhesive 1310 may be screen printed or film patterned to cover the entirety of the top of the walls of the spacer 1210, or may be printed or film patterned in any other suitable pattern onto the top of the walls of the spacer 1210.

At 2302, diaphragms may be mounted on the spacer. For example, the diaphragms 1410 may be mounted on to the spacer 1210 and the transduction elements 620. The diaphragms 1410 may be mounted on to the adhesive 1310 on the top of the walls of the spacer 1210. The perimeters 1420 of the diaphragms 1410 may be adhered to the walls on the top of the spacer 1210 by the adhesive 1310. The diaphragms 1410 may be arranged so that there is little or no gap between the perimeters 1420 of neighboring diaphragms 1410. In some implementations, instead of being separate components, multiple diaphragms 1410 may be part of a single integral component with multiple cups 1430 and multiple perimeters 1420 arranged in any suitable pattern to fit onto the spacer 1210. The waveguides 1710 with protection grids 1720 may be mounted on the diaphragms 1410 before or after the diaphragms 1410 are mounted on the spacer 1210, or may not be used.

At 2304, adhesive may be applied onto transduction elements and/or the diaphragms. For example, the adhesive may be screen printed or film patterned onto the centers of the tops of the transduction elements 620, and/or onto the bottom of the diaphragms 1410 at the location of the cutout 1440 of the cup 1430.

At 2306, the spacer with diaphragms may be mounted on a PCB mounting board. For example, the spacer 1210 may be mounted on the PCB mounting board 810 and the centers of the diaphragms 1410, which may be the cutouts 1440 in the cups 1430, may be mounted on the center of transduction elements 620. The spacer 1210 may be made of an electrically conductive material or may be made of a non-electrically conductive material and may have vias 1220. The transduction elements 620 may be surrounded by the spacer 1210. The spacer 1210 may have any suitable shape and pattern. For example, the spacer 1210 may be walls around empty cells in a hexagonal tiling pattern. Each empty cell of the spacer 1210 may be of a suitable size to fit around a transduction element 620. The spacer 1210 may be placed on the PCB mounting board 810 so that all, or portions, of the bottom of the walls of the spacer 1210 are on the adhesive 1010 on the PCB mounting board 810, including adhesive 1010 that covers the vias 820 that are not covered by the transduction elements 620. If the spacer 1210 is made of a non-electrically conductive material, vias 1220 in the spacer may be aligned with the vias 820 that are not covered by the transduction elements 620. The vias 1220 may be electrically connected to the vias 820 by, for example, the adhesive 1010. Walls of the spacer 1210 that do not cover one of the vias 820 may not include a via 1220. The walls of the spacer may be of any suitable height, and may, for example, be taller than transduction elements 620.

FIG. 24 shows an example procedure suitable for piezoelectric transducer array fabrication according to an implementation of the disclosed subject matter. At 2400, adhesive may be applied onto transduction elements. For example, an electrically conductive adhesive may screen printed or film patterned onto the center of the tops of the transduction elements 620 mounted on the PCB mounting board 810.

At 2402, a spacer/diaphragm component may be mounted on a PCB mounting board and transduction elements. For example, the spacer/diaphragm component 1800 may include both the spacer 1210 and the diaphragms 1410 as a single integral component. The spacer/diaphragm component 1800 may be mounted on the PCB mounting board 810 and the transduction elements 620, for example, on the adhesive 1320. The cutouts 1440 and the bottom of the cups 1430 of the spacer/diaphragm component 1800 may be mounted on the adhesive 1320 at the center of the transduction elements 620.

At 2404, adhesive may be applied onto the spacer/diaphragm component. For example, the adhesive 1610 may be any suitable electrically adhesive which may be screen printed or film patterned on the spacer/diaphragm component 1800, for example, on the top sides of the diaphragms 1410 on the perimeters 1420 of the diaphragms 1410 using any suitable screen-printing or film transfer techniques and equipment. The adhesive 1610 may be screen printed or film patterned to cover the entirety of the perimeters 1420 of the diaphragms 1410 or may be printed in any other suitable pattern onto the perimeters 1420 of the diaphragms 1410. The adhesive 1610 may, for example, encircle each of the cups 1430 of the diaphragms 1410. The adhesive 1610 may be on top of the perimeters 1420 of the diaphragms 1410 and may be aligned with top of the walls of the spacer 1210.

At 2406, waveguides may be mounted on the spacer/diaphragm component. For example, the waveguides 1710 with protection grids 1720 may be mounted on the spacer/diaphragm component 1800 on the adhesive 1610.

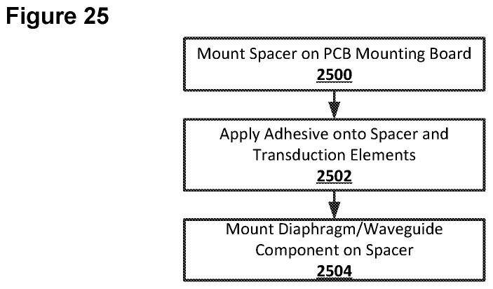

FIG. 25 shows an example procedure suitable for piezoelectric transducer array fabrication according to an implementation of the disclosed subject matter. At 2500, a spacer may be mounted on the PCB mounting board. For example, the spacer 1210 may be mounted on the PCB mounting board 810. The spacer 1210 may be made of an electrically conductive material or may be made of a non-electrically conductive material and may have vias 1220. The transduction elements 620 may be surrounded by the spacer 1210. The spacer 1210 may have any suitable shape and pattern. For example, the spacer 1210 may be walls around empty cells in a hexagonal tiling pattern. Each empty cell of the spacer 1210 may be of a suitable size to fit around a transduction element 620. The spacer 1210 may be placed on the PCB mounting board 810 so that all, or portions, of the bottom of the walls of the spacer 1210 are on the adhesive 1010 on the PCB mounting board 810, including adhesive 1010 that covers the vias 820 that are not covered by the transduction elements 620. If the spacer 1210 is made of a non-electrically conductive material, vias 1220 in the spacer may be aligned with the vias 820 that are not covered by the transduction elements 620. The vias 1220 may be electrically connected to the vias 820 by, for example, the adhesive 1010. Walls of the spacer 1210 that do not cover one of the vias 820 may not include a via 1220. The walls of the spacer may be of any suitable height, and may, for example, be taller than transduction elements 620.

At 2502, adhesive may be applied on the spacer and transduction elements. For example, the adhesive 1310 may be screen printed or film patterned on top of the spacer 1210 and the adhesive 1320 may be screen printed or film patterned at the centers of the tops of the transduction elements 620. The adhesive 1310 may be any suitable electrically conductive adhesive. The adhesive 1310 may be screen printed or film patterned onto the top of the walls of the spacer 1210. The adhesive 1310 may cover the vias 1210. The adhesive 1320 may be screen printed or film patterned at the centers of the tops of the transduction elements 620. The adhesive 1310 may be screen printed or film patterned using any suitable screen-printing or film transfer techniques and equipment. The adhesive 1310 may be screen printed or film patterned to cover the entirety of the top of the walls of the spacer 1210, or may be printed in any other suitable pattern onto the top of the walls of the spacer 1210.

At 2504, a diaphragm/waveguide component may be mounted on the spacer. For example, the diaphragm/waveguide component 1900 may be mounted on to the spacer 1210 and the transduction elements 620. The diaphragm/waveguide component 1900 may include both the diaphragms 1410 and the waveguide 1710 and protection grid 1720 as a single integral component. The diaphragms 1410 of the diaphragm/waveguide component 1900 may be mounted on to the adhesive 1310 on the top of the walls of the spacer 1210. The perimeters 1420 of the diaphragms 1410 may be adhered to the walls on the top of the spacer 1210 by the adhesive 1310. The centers of the diaphragms 1410, which may be the cutouts 1440 in the cups 1430, may be mounted on to the adhesive 1320 at the center of transduction elements 620. This may create a mechanical connection between the transduction elements 620 and the diaphragms 1410 so that, for example, flexure of a piece of piezoelectric material 220 may cause movement of the diaphragm 1410 adhered to that piece of piezoelectric material, and movement of the diaphragm 1410 due to forces such as, for example, sound waves, may cause flexure of the piece of piezoelectric material 220 to which the diaphragm 1410 is adhered.

The foregoing description, for purpose of explanation, has been described with reference to specific embodiments. However, the illustrative discussions above are not intended to be exhaustive or to limit embodiments of the disclosed subject matter to the precise forms disclosed. Many modifications and variations are possible in view of the above teachings. The embodiments were chosen and described in order to explain the principles of embodiments of the disclosed subject matter and their practical applications, to thereby enable others skilled in the art to utilize those embodiments as well as various embodiments with various modifications as may be suited to the particular use contemplated.

1. A method for piezoelectric transducer array fabrication comprising:
dicing a sheet of piezoelectric material into pieces of piezoelectric material;
spin coating a sheet of elastic layer material with adhesive;
placing the pieces of piezoelectric material onto the sheet of elastic layer material;
applying pressure to the pieces of piezoelectric material and the sheet of elastic layer material and curing the adhesive;
cutting transduction elements from the pieces of piezoelectric material and the sheet of elastic layer material;
mounting electronics on a PCB mounting board comprising traces and vias;
applying adhesive onto the PCB mounting board;
mounting the transduction elements on the PCB mounting board;
mounting a spacer on the PCB mounting board;
applying adhesive onto the spacer and the transduction elements; and
mounting diaphragms on the spacer.

2. The method of claim 1, further comprising:
applying adhesive onto the diaphragms; and
mounting waveguides on the diaphragms.

3. The method of claim 2, wherein protection grids are attached to the waveguides.

4. The method of claim 1, wherein the adhesive applied onto the PCB mounting board is electrically conductive.

5. The method of claim 1, wherein each of the transduction elements is mounted on the PCB mounting board to cover one via of the PCB mounting board.

6. The method of claim 1, wherein the spacer comprises vias that are aligned with vias of the PCB mounting board when the spacer is mounted on the PCB mounting board.

7. The method of claim 1, wherein each of the diaphragms comprises a cup that is mounted on one of the transduction elements when the diaphragms are mounted on the spacer.

8. The method of claim 1, wherein the diaphragms comprise an electrically conductive material.

9. A method for piezoelectric transducer array fabrication comprising:
applying adhesive onto a PCB mounting board comprising vias, wherein the adhesive is electrically conductive; and
mounting transduction elements to the PCB mounting board such that each of the transduction elements covers one of the vias on the PCB mounting board, wherein each of the transduction elements comprises a bimorph with an elastic layer adhered to a piece of piezoelectric material.

10. The method of claim 9, further comprising:
applying adhesive onto a spacer;
mounting diaphragms on the spacer;
applying adhesive onto either or both of the transduction elements and the bottoms of cups of the diaphragms;
applying adhesive to one or both of the bottom of the spacer and the PCB mounting board; and
mounting the spacer with the diaphragms on the PCB mounting board.

11. The method of claim 10, further comprising:
applying adhesive onto perimeters of the diaphragms; and
mounting waveguides on the diaphragms.

12. The method of claim 9, further comprising:
applying adhesive onto the transduction elements; and
mounting a spacer/diaphragm component on the PCB mounting board and the transduction elements, wherein the spacer/diaphragm component comprises a spacer and diaphragms as a single integral component.

13. The method of claim 9, further comprising:
mounting a spacer on the PCB mounting board;
applying adhesive onto the spacer and the transduction elements; and
mounting a diaphragm/waveguide component on the spacer and the transduction elements, wherein the diaphragm/waveguide component comprises diaphragms and waveguides as a single integral component.

14. A method for piezoelectric transducer array fabrication comprising:
mounting electronics on a PCB mounting board comprising traces and vias;
applying adhesive onto the PCB mounting board;
mounting transduction elements on the PCB mounting board;
mounting a spacer on the PCB mounting board using either adhesive applied to the PCB mounting board or adhesive applied to the bottom of the spacer;
applying adhesive onto the spacer and the transduction elements; and
mounting diaphragms on the spacer and the transduction elements.

15. The method of claim 14, further comprising, before mounting the transduction elements to the PCB mounting board:
dicing a sheet of piezoelectric material into pieces of piezoelectric material;
coating a sheet of elastic layer material with adhesive;
placing the pieces of piezoelectric material onto the sheet of elastic layer material;
applying pressure to the pieces of piezoelectric material and the sheet of elastic layer material and curing the adhesive;
cutting the transduction elements from the pieces of piezoelectric material and the sheet of elastic layer material;

16. The method of claim 15, wherein cutting the transduction elements from the pieces of piezoelectric material and the sheet of elastic layer material comprising laser cutting or chemically etching the sheet of elastic layer material in a shape around each piece of the pieces of piezoelectric material.

17. The method of claim 14, further comprising:
applying adhesive onto perimeters of the diaphragms; and
mounting waveguides on the diaphragms.

18. The method of claim 14, wherein the diaphragms comprise a single integral component.

19. The method of claim 14, wherein the spacer comprises walls forming patterned cells that fit around the transduction elements on the PCB mounting board.

20. The method of claim 14, wherein each transduction element covers a via of the PCB mounting board and wherein the spacer cover a via of the PCB mounting board for each transduction element on the PCB mounting board.
